(19) United States
(12) Patent Application Publication
(10) Pub. No.: US 2026/0173286 A1
(43) Pub. Date: Jun. 18, 2026

(54) ELECTRONIC DEVICE

(71) Applicant: Luxshare Precision Industry Company Limited, SHENZHEN (CN)

(72) Inventors: Shumin Qiu, SHENZHEN (CN); Weiqiang Yao, SHENZHEN (CN)

(73) Assignee: Luxshare Precision Industry Company Limited, SHENZHEN (CN)

(21) Appl. No.: 19/414,854

(22) Filed: Dec. 10, 2025

(30) Foreign Application Priority Data
Dec. 17, 2024 (CN) 202411865414.0
Dec. 17, 2024 (CN) 202411869577.6

(51) Int. Cl. H05K 5/02

(52) U.S. Cl. CPC H05K 5/0247

(57) ABSTRACT

An electronic device includes a housing, a metal connector, a main control board, a fixed bracket, a conductive layer, an elastic conductive contact, and a flexible circuit board. The metal connector is connected in an installation slot on the housing. The fixed bracket and the main control board are disposed inside the housing. The conductive layer is formed on the top surface, the connection surface, and the outer side surface of the fixed bracket using a PDS process. Two ends of the elastic conductive contact are electrically connected to the metal connector and the conductive layer respectively. One end of the flexible circuit board is electrically connected to the conductive layer, and another end of the flexible circuit board is electrically connected to the main control board.

### CLAIM OF PRIORITY AND CROSS-REFERENCE TO RELATED APPLICATION(S)

This application claims the benefits of Chinese Patent Application No. 202411869577.6, filed on Dec. 17, 2024, and Chinese Patent Application No. 202411865414.0, filed on Dec. 17, 2024. The entireties of the above applications are hereby incorporated by reference.

### BACKGROUND OF THE DISCLOSURE

### 1. Field of the Disclosure

The present disclosure relates to the field of electronic product technology, and particularly to an electronic device.

### 2. Description of the Related Art

Currently, many electronic products use metal connectors on plastic housings for aesthetics and high quality, but overlook the issue that metal connectors need to be grounded. This may easily lead to static electricity generated on the metal connector damaging internal electronic components, thereby causing serious problems such as crashes or even damage.

### BRIEF DESCRIPTION OF THE DISCLOSURE

In view of this, embodiments of the present disclosure provide an electronic device with a simple grounding method.

In a first aspect, an embodiment of the present disclosure provides an electronic device. The electronic device includes: a housing, internally provided with a cavity, an outer side of the housing being provided with an installation slot and a first installation through hole, the first installation through hole being disposed within the installation slot and connecting the installation slot and the cavity; a metal connector, connected within the installation slot; a main control board, disposed within the cavity; a fixed bracket, disposed within the cavity, a top surface and an outer side surface of the fixed bracket being connected by a connection surface; a conductive layer, disposed on the top surface, the connection surface, and the outer side surface of the fixed bracket; an elastic conductive contact, installed in the first installation through hole, two ends of the elastic conductive contact being electrically connected to the metal connector and the conductive layer respectively, a length of the elastic conductive contact being greater than or equal to a depth of the first installation through hole; and a flexible circuit board, disposed on a side of an inner side surface of the fixed bracket, one end of the flexible circuit board being electrically connected to the conductive layer located on the top surface of the fixed bracket, another end of the flexible circuit board being electrically connected to the main control board, static electricity generated on the metal connector being discharged and conducted to a grounding point of the main control board sequentially through the elastic conductive contact, the conductive layer, and the flexible circuit board.

In a second aspect, an embodiment of the present disclosure further provides an electronic device. The electronic device includes: a housing; a metal connector, connected to the housing; a main control board, disposed inside the housing; a fixed bracket, disposed inside the housing; a conductive layer, disposed on the fixed bracket; an elastic conductive contact, installed on the housing, two ends of the elastic conductive contact being electrically connected to the metal connector and the conductive layer respectively; and a flexible circuit board, disposed on a side of an inner side surface of the fixed bracket, an exposed copper region at one end of the flexible circuit board being electrically connected to the conductive layer through conductive adhesive, another end of the flexible circuit board being electrically connected to the main control board, static electricity generated on the metal connector being discharged and conducted to a grounding point of the main control board sequentially through the elastic conductive contact, the conductive layer, and the flexible circuit board.

The electronic device of the embodiments of the present disclosure includes a housing, a metal connector, a main control board, a fixed bracket, a conductive layer, an elastic conductive contact, and a flexible circuit board. The metal connector is connected in an installation slot on the housing. The fixed bracket and the main control board are disposed inside the housing. The conductive layer is formed on the top surface, the connection surface, and the outer side surface of the fixed bracket using a PDS process. Two ends of the elastic conductive contact are electrically connected to the metal connector and the conductive layer respectively. One end of the flexible circuit board is electrically connected to the conductive layer, and another end of the flexible circuit board is electrically connected to the main control board.

### BRIEF DESCRIPTION OF THE DRAWINGS

Through the following description of the embodiments of the present disclosure with reference to the accompanying drawings, the above and other objects, features, and advantages of the present disclosure will become more apparent. In the drawings:

FIG. 1 is a schematic structural diagram of an electronic device according to an embodiment of the present disclosure;

FIG. 2 is an exploded view of the electronic device according to an embodiment of the present disclosure;

FIG. 3 is a first perspective schematic structural diagram of a fixed bracket and an abutment bracket according to an embodiment of the present disclosure;

FIG. 4 is a second perspective schematic structural diagram of the fixed bracket and the abutment bracket according to an embodiment of the present disclosure;

FIG. 5 is a schematic structural diagram of a housing according to an embodiment of the present disclosure;

FIG. 6 is a cross-sectional view of the electronic device according to an embodiment of the present disclosure;

FIG. 7 is a partial schematic diagram of the housing according to an embodiment of the present disclosure.

### DETAILED DESCRIPTION OF EMBODIMENTS OF THE DISCLOSURE

The present application is described below based on embodiments, but the present application is not limited to these embodiments. In the following detailed description of the present application, some specific details are described in detail. Those skilled in the art may fully understand the present application without the description of these detail parts. In order to avoid obscuring the essence of the present application, well-known methods, procedures, processes, elements, and circuits are not described in detail.

Furthermore, those of ordinary skill in the art should understand that the drawings provided herein are for illustrative purposes, and the drawings are not necessarily drawn to scale.

Unless otherwise clearly specified and defined, terms such as “install”, “connect”, “link”, “fix” should be understood broadly. For example, it may be a fixed connection, a detachable connection, or integrated into one; it may be a mechanical connection, an electrical connection; it may be a direct connection, or an indirect connection through an intermediate medium; it may be the internal communication between two elements or the interaction relationship between two elements, unless otherwise explicitly defined. Those of ordinary skill in the art may understand the specific meanings of the above terms in the present application according to the specific situation.

Unless the context clearly requires otherwise, throughout the description and the claims, the words “comprise”, “include” and the like are to be construed in an inclusive sense as opposed to an exclusive or exhaustive sense; that is to say, in the sense of “including but not limited to”.

In the description of the present application, it should be understood that the terms “first”, “second”, etc. are used for descriptive purposes only and cannot be understood as indicating or implying relative importance. In addition, in the description of the present application, unless otherwise stated, “a plurality of” means two or more.

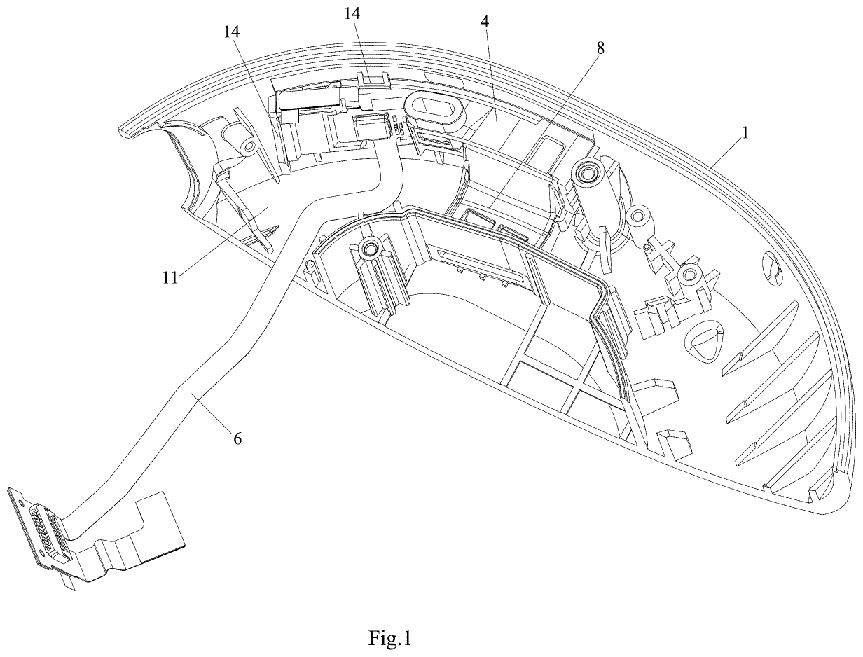

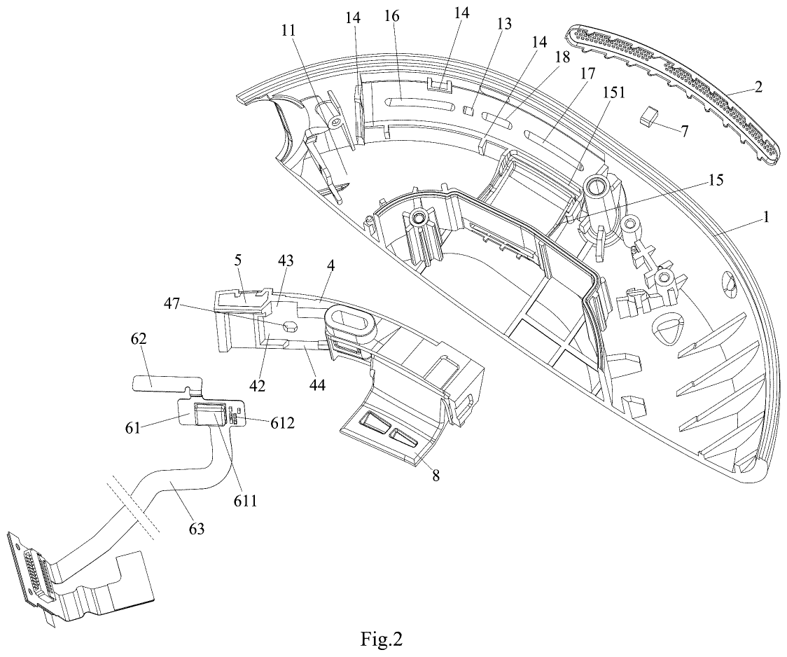

FIG. 1 and FIG. 2 are schematic diagrams of the electronic device of this embodiment. The electronic device may be 3C consumer electronic products such as earphones, watches, headphones, TWS earphones, bracelets, etc. The electronic device includes a housing 1, a metal connector 2, a fixed bracket 4, a conductive layer 5, a flexible circuit board 6, and a main control board, as shown in FIG. 1 and FIG. 2. The housing 1 is internally provided with a cavity 11, which is used to place the fixed bracket 4, conductive layer 5, flexible circuit board 6, main control board, etc.

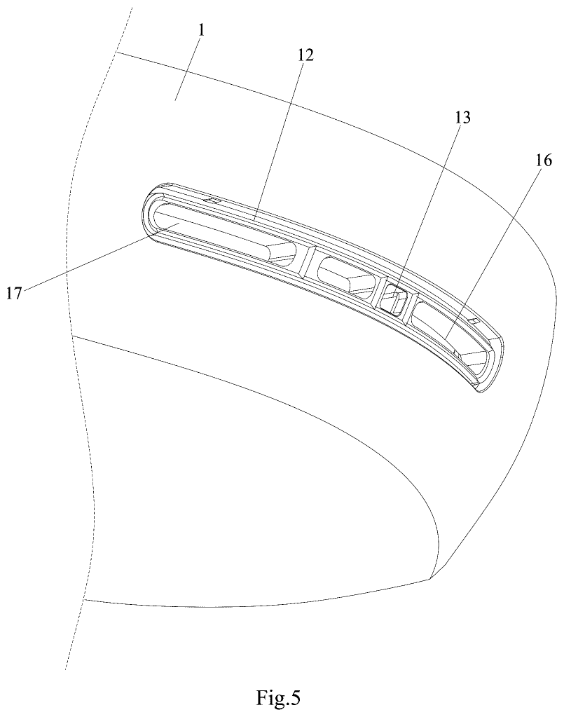

As shown in FIG. 5, the outer side of the housing 1 is provided with an installation slot 12, which may communicate with the inside of the cavity 11. The metal connector 2 is connected in the installation slot 12, which may improve the aesthetics of the electronic device and other quality requirements, such as acoustic performance. When the electronic device is an earphone, the installation slot 12 may be a sound vent, and the metal connector 2 may be a dust screen; at this time, the installation slot 12 is used to connect the cavity 11 with the external environment, facilitating the inflow and outflow of external air, balancing the internal pressure of the earphone, bringing better auditory effects, and improving the acoustic performance of the earphone; the metal connector 2, as a dust screen, may isolate impurities from the external environment outside the dust screen, preventing impurities from entering the cavity and affecting the acoustic performance of the earphone.

As shown in FIG. 1, the fixed bracket 4 is disposed in the cavity 11 and is relatively fixedly connected to the housing 1 at a position corresponding to the metal connector 2. Optionally, the outer side surface of the fixed bracket 4 is configured as a curved surface that conforms to the inner side surface of the housing 1, so that the fixed bracket 4 may be attached and fixedly connected to the housing 1, improving connection stability.

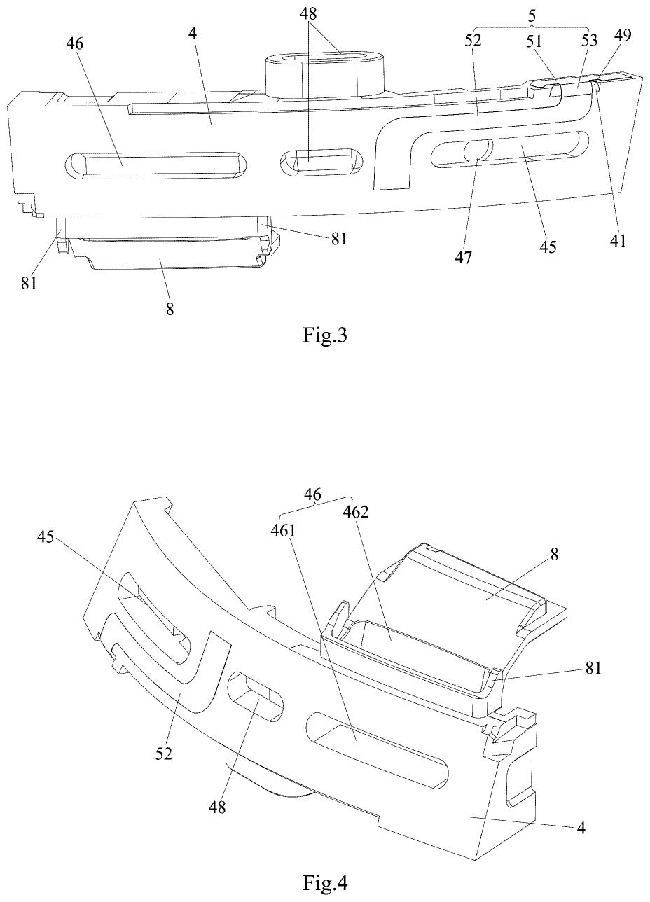

As shown in FIG. 3 and FIG. 4, the fixed bracket 4 is provided with a first printing formation area, a second printing formation area, and an arc-shaped printing formation area 41. The first printing formation area is disposed on the top surface of the fixed bracket 4 and close to the edge position. The second printing formation area is disposed on the outer side surface of the fixed bracket 4. The arc-shaped printing formation area 41 is disposed on the connection surface 49. The connection surface 49 connects the top surface and the outer side surface of the fixed bracket 4. The arc-shaped printing formation area 41 connects the first printing formation area and the second printing formation area. The outer side surface of the fixed bracket 4 refers to the surface in contact with the housing 1. The first printing formation area, the second printing formation area, and the arc-shaped printing formation area 41 are areas formed by a printing directly structured (PDS) process. The arc-shaped printing formation area 41 connects the top surface and the outer side surface, avoiding the influence of stress generated by right-angle turns in the printed structure. The first printing formation area is disposed on the top surface of the fixed bracket 4 and close to the edge position, so that the conductive layer 5 connected to the printed structure thereon is located at the edge of the cavity 11, avoiding impact on internal components of the electronic device and reducing the size of the electronic device. In this embodiment, the angle between the first printing formation area and the second printing formation area is an acute angle, meaning the angle formed after extending the planes where they are located is an acute angle. The planes of the first printing formation area and the second printing formation area are transitionally connected through the arc-shaped printing formation area 41, improving the conductive performance after the conductive layer 5 is formed thereon.

The conductive layer 5 is formed on the first printing formation area, the second printing formation area, and the arc-shaped printing formation area 41 of the fixed bracket 4 using the printing directly structured (PDS) process. As shown in FIG. 1 and FIG. 2, the flexible circuit board 6 is disposed on the side of the inner side surface of the fixed bracket 4. One end of the flexible circuit board 6 is electrically connected to the conductive layer 5 located on the first printing formation area (i.e., the top surface of the fixed bracket 4), and another end of the flexible circuit board 6 is electrically connected to the main control board. The conductive layer 5 located on the second printing formation area (i.e., the outer side surface of the fixed bracket 4) is electrically connected to the metal connector 2. When the electronic device is in use or under test, static electricity generated on the metal connector 2 is discharged and conducted to the grounding point of the main control board through the conductive layer 5 and the flexible circuit board 6, thereby leading it to the ground, so that it does not cause damage to other electronic components inside the electronic device, improving the safety of the electronic device.

As shown in FIG. 3, the conductive layer 5 includes a first conductive part 51, a second conductive part 52, and a connection conductive part 53. The first conductive part 51 is formed in the first printing formation area (i.e., the top surface of the fixed bracket 4 and close to the edge position) and is used for electrical connection with the flexible circuit board 6; the second conductive part 52 is disposed in the second printing formation area (i.e., the outer side surface of the fixed bracket 4) and is used for electrical connection with the metal connector 2; the connection conductive part 53 is formed in the arc-shaped printing formation area 41 and its two ends are electrically connected to the first conductive part 51 and the second conductive part 52 respectively. The connection conductive part 53 is formed in the arc-shaped printing formation area 41, which may avoid sharp corners at the connection between the first conductive part 51 and the second conductive part 52, improving the overall conductive performance of the conductive layer 5. Sharp corners in the conductive layer 5 are prone to wear and reduce conductive performance.

The electronic device provided by the embodiments of the present application uses the PDS process to form the conductive layer on the fixed bracket, making the connection between the conductive layer and the fixed bracket more stable and less prone to falling off, while not occupying the internal space of the electronic device, which is conducive to the miniaturization of the electronic device.

In other optional embodiments, the conductive layer 5 may also be formed on the fixed bracket 4 using a laser direct structuring (LDS) process.

Further, the housing 1 is provided with a first installation through hole 13, as shown in FIG. 2 and FIG. 5. The first installation through hole 13 is located within the area enclosed by the installation slot 12, and the first installation through hole 13 may connect the installation slot 12 and the cavity 11. The electronic device further includes an elastic conductive contact 7, as shown in FIG. 2. The elastic conductive contact 7 is installed in the first installation through hole 13. The position of the first installation through hole 13 is opposite to the second conductive part 52 on the fixed bracket 4 fixed inside the housing 1, so that the two ends of the elastic conductive contact 7 installed in the first installation through hole 13 may be electrically connected to the metal connector 2 and the conductive layer 5 (i.e., the second conductive part 52) respectively, thereby achieving discharge of the metal connector 2.

Optionally, the length of the elastic conductive contact 7 is not less than the depth of the first installation through hole 13. Specifically in this embodiment, the length of the elastic conductive contact 7 is slightly longer than the depth of the first installation through hole 13, so that after the fixed bracket 4, the metal connector 2, and the housing 1 are fixedly connected, they may compress both ends of the elastic conductive contact 7 to ensure that the elastic conductive contact 7 always maintains electrical connection with the metal connector 2 and the conductive layer 5. The material of the elastic conductive contact 7 is conductive silicone or conductive rubber. Conductive silicone and conductive rubber are made by uniformly distributing conductive particles such as glass coated with silver, aluminum coated with silver, silver, etc., in silicone or rubber. Good conductive performance is achieved by pressure causing contact between the conductive particles. In other implementations, the connection method between the metal connector 2 and the conductive layer 5 may also use other electrical connection methods, such as conductive adhesive bonding.

In this embodiment, the first installation through hole 13 is located near the center of the installation slot 12. The second conductive part 52 is extendedly set on the outer side surface of the fixed bracket 4 according to the position of the first installation through hole 13, so that the end of the second conductive part 52 is directly opposite the first installation through hole 13, thereby enabling the elastic conductive contact 7 to achieve electrical connection with the second conductive part 52.

As shown in FIG. 1 and FIG. 2, the flexible circuit board 6 includes a first flexible part 61, a second flexible part 62, and a third flexible part 63 connected to each other. The second flexible part 62 and the third flexible part 63 are connected to the upper and lower sides of the first flexible part 61 respectively. The second flexible part 62 is bendably connected to one side of the first flexible part 61 and extends to above the top surface of the fixed bracket 4. The first flexible part 61 is fixed on the inner side surface of the fixed bracket 4. The second flexible part 62 is electrically connected to the first conductive part 51. The third flexible part 63 extends along the bottom surface of the cavity 11 to be electrically connected to the main control board, thereby realizing the electrical connection between the conductive layer 5 and the main control board, so that static electricity on the metal connector 2 may be conducted to the grounding point of the main control board, improving the safety performance of the electronic device. The arrangement of the first flexible part 61, the second flexible part 62, and the third flexible part 63 does not affect the arrangement of other electronic components inside the electronic device.

As shown in FIG. 2, the inner side surface of the fixed bracket 4 is provided with an accommodation groove 42, a first avoidance groove 43, and a second avoidance groove 44. The accommodation groove 42 is disposed close to the first printing formation area. The first avoidance groove 43 and the second avoidance groove 44 are respectively disposed on the upper and lower sides of the accommodation groove 42. The first avoidance groove 43 connects the accommodation groove 42 and the first printing formation area. The second avoidance groove 44 connects the accommodation groove 42 and the cavity 11. The first flexible part 61 is fixed in the accommodation groove 42. The second flexible part 62 extends through the first avoidance groove 43 to the first printing formation area. The exposed copper region of the second flexible part 62 is electrically connected above the first conductive part 51. The third flexible part 63 extends through the second avoidance groove 44 into the cavity 11 and is electrically connected to the main control board. The first avoidance groove 43 and the second avoidance groove 44 allow the flexible circuit board 6 to be installed flat or with a smooth transition when connected inside the housing 1, avoiding stress concentration and other issues. The first flexible part 61 may be pasted in the accommodation groove 42 by glue or pressure-sensitive adhesive, etc. The exposed copper region of the second flexible part 62 may be connected above the first conductive part 51 by laser welding or conductive adhesive bonding. The third flexible part 63 may be pasted in the cavity 11 by glue or pressure-sensitive adhesive, etc.

The shape of the accommodation groove 42 matches the shape of the first flexible part 61 to better fix the first flexible part 61. In this embodiment, the accommodation groove 42 and the first flexible part 61 are rectangular structures. A microphone 611 and an electronic component 612 are connected to the first flexible part 61 for realizing specific electronic functions, such as collecting and processing sound in devices like phones and watches, used for voice command recognition, calls, etc. The second flexible part 62 and the first conductive part 51 are conformal structures. The area of the conductive adhesive is the same as the area of the exposed copper region of the second flexible part 62, thereby improving the dual stability of physical connection and electrical connection between the second flexible part 62 and the first conductive part 51. Optionally, the second flexible part 62 and the first conductive part 51 are rectangular.

As shown in FIG. 2, the inner side of the housing 1 is provided with a plurality of limiting blocks 14. The plurality of limiting blocks 14 are snap-connected to the outer side of the fixed bracket 4, thereby fixing the fixed bracket 4 to the housing 1. The installation slot 12 is located within the area enclosed by the plurality of limiting blocks 14, thereby enabling the electrical connection between the metal connector 2 and the conductive layer 5 on the fixed bracket 4, etc. In this embodiment, the plurality of limiting blocks 14 are respectively disposed on the outer sides of the four side surfaces of the fixed bracket 4 to clamp and fix the fixed bracket 4 from four directions. The shape and size of the limiting blocks 14 are not limited, as long as they meet the clamping and snap-fitting requirements.

One side of the fixed bracket 4 is further connected with an abutment bracket 8 extending toward the inner side of the cavity 11. The abutment bracket 8 protrudes with a snap-fit part 81, as shown in FIG. 3 and FIG. 4. The inner side of the housing 1 is further provided with an annular limiting boss 15. The annular limiting boss 15 is provided with a card slot 151, as shown in FIG. 2. The annular limiting boss 15 is located on one side of the limiting blocks 14, specifically disposed on the side of the plurality of limiting blocks 14 close to the bottom of the cavity 11. After the fixed bracket 4 is fixed by the limiting blocks 14, the abutment bracket 8 is installed on the annular limiting boss 15, and the snap-fit part 81 is inserted into the card slot 151, thereby further improving the stability of the connection of the fixed bracket 4.

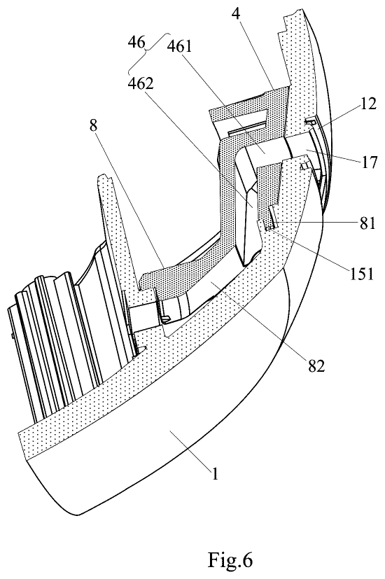

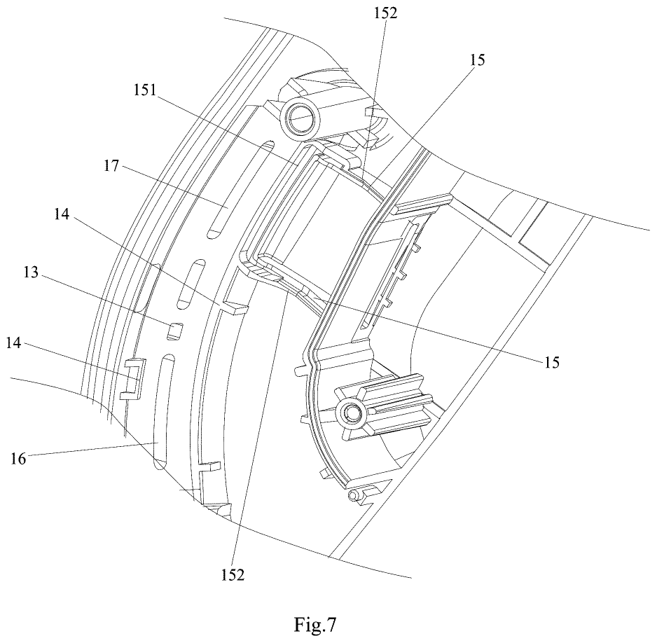

As shown in FIG. 7, the peripheral upper part of the annular limiting boss 15 protrudes with an annular baffle 152. The annular baffle 152 surrounds and blocks the peripheral outer side of the abutment bracket 8, thereby further improving the stability of the connection of the fixed bracket 4. As shown in FIG. 6, a sound reception channel 82 is formed between the abutment bracket 8 and the housing 1. The sound reception channel 82 communicates with the cavity 11, ensuring the communication quality and reliability of the electronic device.

As shown in FIG. 5, the housing 1 further includes a first through hole 16 and a second through hole 17. The first through hole 16 and the second through hole 17 are disposed within the area enclosed by the installation slot 12. The first through hole 16 and the second through hole 17 may both connect the installation slot 12 and the cavity 11, thereby connecting the inside and outside of the electronic device.

As shown in FIG. 3 and FIG. 4, the outer side surface of the fixed bracket 4 further includes a first sound pickup hole 45 and a second sound pickup hole 46. The first sound pickup hole 45 and the accommodation groove 42 are connected by a connection through hole 47. The first sound pickup hole 45 and the first through hole 16 are oppositely disposed and communicate, allowing the microphone 611 to pick up sound or allow air communication through the accommodation groove 42, the first sound pickup hole 45, and the first through hole 16. The first sound pickup hole 45 is a long strip structure, which may increase the sound pickup area and improve the sound pickup effect. The second sound pickup hole 46 communicates with the sound reception channel 82. The second sound pickup hole 46 and the second through hole 17 are oppositely disposed and communicate, facilitating the inflow and outflow of external air and balancing the internal pressure of the electronic device.

In this embodiment, the second sound pickup hole 46 includes a transverse sound pickup hole 461 and a longitudinal sound pickup hole 462 communicating with each other, as shown in FIG. 6. The transverse sound pickup hole 461 and the second through hole 17 are oppositely disposed and communicate. The longitudinal sound pickup hole 462 communicates with the sound reception channel 82, thereby facilitating the inflow and outflow of external air and balancing the internal pressure of the electronic device. The arrangement of the second sound pickup hole 46 allows the pressure near the middle of the electronic device to be balanced quickly, improving the stability of the electronic device.

The fixed bracket 4 may be provided with a penetrating third sound pickup hole 48 according to requirements. The housing 1 is provided with a third through hole 18 at a position corresponding to the third sound pickup hole 48, which may further facilitate the inflow and outflow of air and balance the internal pressure of the electronic device.

In this embodiment, the first installation through hole 13 is disposed between the first through hole 16 and the second through hole 17, so that the two ends of the elastic conductive contact 7 abut against the middle positions of the fixed bracket 4 and the metal connector 2 respectively, avoiding uneven force and warping, which affects the installation effect and the stability of the electrical connection. The second conductive part 52 is located above the first sound pickup hole 45, and one end of the second conductive part 52 extends upward to connect with the connection conductive part 53, and another end of the second conductive part 52 extends downward between the first sound pickup hole 45 and the second sound pickup hole 46 to connect with the elastic conductive contact 7.

To further improve the safety performance of the electronic device, the material of the housing 1 and the fixed bracket 4 of the electronic device may be made of insulating materials such as plastic or rubber.

The electronic device of this embodiment includes a housing, a metal connector, a main control board, a fixed bracket, a conductive layer, an elastic conductive contact, and a flexible circuit board. The metal connector is connected in an installation slot on the housing. The fixed bracket and the main control board are disposed inside the housing. The conductive layer is formed on the top surface, the connection surface, and the outer side surface of the fixed bracket using a PDS process. Two ends of the elastic conductive contact are electrically connected to the metal connector and the conductive layer respectively. One end of the flexible circuit board is electrically connected to the conductive layer, and another end of the flexible circuit board is electrically connected to the main control board, thereby discharging static electricity generated on the metal connector to a grounding point of the main control board through the flexible circuit board. The grounding method for the metal connector in this electronic device is simple, the number of parts is small, the assembly process is simplified, and the function of electrostatic protection is achieved.

The above descriptions are only preferred embodiments of the present application and are not intended to limit the present application. For those skilled in the art, the present application may have various modifications and changes. Any modifications, equivalent replacements, improvements, etc., made within the spirit and principle of the present application shall be included within the protection scope of the present application.

I/We claim:

1. An electronic device, comprising:
a housing, internally provided with a cavity, an outer side of the housing being provided with an installation slot and a first installation through hole, the first installation through hole being disposed within the installation slot and connecting the installation slot and the cavity;
a metal connector, connected within the installation slot;
a main control board, disposed within the cavity;
a fixed bracket, disposed within the cavity, a top surface and an outer side surface of the fixed bracket being connected by a connection surface;
a conductive layer, disposed on the top surface, the connection surface, and the outer side surface of the fixed bracket;
an elastic conductive contact, installed in the first installation through hole, two ends of the elastic conductive contact being electrically connected to the metal connector and the conductive layer respectively, a length of the elastic conductive contact being greater than or equal to a depth of the first installation through hole; and
a flexible circuit board, disposed on a side of an inner side surface of the fixed bracket, one end of the flexible circuit board being electrically connected to the conductive layer located on the top surface of the fixed bracket, another end of the flexible circuit board being electrically connected to the main control board, static electricity generated on the metal connector being discharged and conducted to a grounding point of the main control board sequentially through the elastic conductive contact, the conductive layer, and the flexible circuit board.

2. The electronic device according to claim 1, wherein the fixed bracket is provided with a first printing formation area, a second printing formation area, and an arc-shaped printing formation area, the first printing formation area is disposed on the top surface of the fixed bracket and close to an edge position, the second printing formation area is disposed on the outer side surface of the fixed bracket, the arc-shaped printing formation area is disposed on the connection surface, the arc-shaped printing formation area connects the first printing formation area and the second printing formation area.

3. The electronic device according to claim 2, wherein the conductive layer comprises a first conductive part, a second conductive part, and a connection conductive part, the first conductive part is formed in the first printing formation area, the second conductive part is disposed in the second printing formation area, the connection conductive part is formed in the arc-shaped printing formation area and its two ends are electrically connected to the first conductive part and the second conductive part respectively, the first conductive part is electrically connected to the flexible circuit board.

4. The electronic device according to claim 3, wherein a material of the elastic conductive contact is conductive silicone or conductive rubber.

5. The electronic device according to claim 3, wherein the inner side surface of the fixed bracket is provided with an accommodation groove, a first avoidance groove, and a second avoidance groove, the first avoidance groove and the second avoidance groove are respectively disposed on upper and lower sides of the accommodation groove, the first avoidance groove connects the accommodation groove and the first printing formation area, the second avoidance groove connects the accommodation groove and the cavity.

6. The electronic device according to claim 5, wherein the flexible circuit board comprises:
a first flexible part, fixed in the accommodation groove, a microphone and an electronic component being connected to the first flexible part;
a second flexible part, bendably connected to one side of the first flexible part, extending through the first avoidance groove to the first printing formation area, an exposed copper region of the second flexible part being connected above the first conductive part through conductive adhesive; and
a third flexible part, connected to another side of the first flexible part, the third flexible part extending through the second avoidance groove into the cavity and being electrically connected to the main control board.

7. The electronic device according to claim 6, wherein the second flexible part and the first conductive part are conformal structures, an area of the conductive adhesive is the same as an area of the exposed copper region of the second flexible part.

8. The electronic device according to claim 5, wherein an inner side of the housing is provided with a plurality of limiting blocks, the plurality of limiting blocks are snap-connected to an outer side of the fixed bracket.

9. The electronic device according to claim 8, wherein the installation slot is located within an area enclosed by the plurality of limiting blocks.

10. The electronic device according to claim 8, wherein one side of the fixed bracket is further connected with an abutment bracket extending toward an inner side of the cavity, an outer side surface of the abutment bracket protrudes with a snap-fit part;
the inner side of the housing is further provided with an annular limiting boss, the annular limiting boss is provided with a card slot, the abutment bracket is installed on the annular limiting boss, the snap-fit part is inserted into the card slot, a sound reception channel communicating with the cavity is formed between the abutment bracket and the housing.

11. The electronic device according to claim 10, wherein the annular limiting boss is disposed on a side of the plurality of limiting blocks close to a bottom of the cavity, a peripheral upper part of the annular limiting boss protrudes with an annular baffle, the annular baffle surrounds and blocks a peripheral outer side of the abutment bracket.

12. The electronic device according to claim 10, wherein the outer side surface of the fixed bracket further comprises a first sound pickup hole and a second sound pickup hole, a connection through hole is provided between the first sound pickup hole and the accommodation groove, the second sound pickup hole communicates with the sound reception channel.

13. The electronic device according to claim 12, wherein the housing further comprises a first through hole and a second through hole communicating with the installation slot, the first sound pickup hole and the first through hole are oppositely disposed and communicate, the second sound pickup hole and the second through hole are oppositely disposed and communicate.

14. The electronic device according to claim 13, wherein the second sound pickup hole comprises a transverse sound pickup hole and a longitudinal sound pickup hole communicating with each other, the transverse sound pickup hole and the second through hole are oppositely disposed and communicate, the longitudinal sound pickup hole communicates with the sound reception channel.

15. The electronic device according to claim 13, wherein the first installation through hole is disposed between the first through hole and the second through hole, the second conductive part is located above the first sound pickup hole, and one end of the second conductive part extends upward to connect with the connection conductive part, another end of the second conductive part extends downward between the first sound pickup hole and the second sound pickup hole to connect with the elastic conductive contact.

16. The electronic device according to claim 1, wherein the outer side surface of the fixed bracket is configured as a curved surface that conforms to an inner side surface of the housing.

17. The electronic device according to claim 2, wherein an angle between the first printing formation area and the second printing formation area is an acute angle.

18. The electronic device according to claim 1, wherein a material of the housing and the fixed bracket is plastic or rubber.

19. The electronic device according to claim 1, wherein a length of the elastic conductive contact is greater than a depth of the first installation through hole.

20. An electronic device, comprising:
a housing;
a metal connector, connected to the housing;
a main control board, disposed inside the housing;
a fixed bracket, disposed inside the housing;
a conductive layer, disposed on the fixed bracket;
an elastic conductive contact, installed on the housing, two ends of the elastic conductive contact being electrically connected to the metal connector and the conductive layer respectively; and
a flexible circuit board, disposed on a side of an inner side surface of the fixed bracket, an exposed copper region at one end of the flexible circuit board being electrically connected to the conductive layer through conductive adhesive, another end of the flexible circuit board being electrically connected to the main control board, static electricity generated on the metal connector being discharged and conducted to a grounding point of the main control board sequentially through the elastic conductive contact, the conductive layer, and the flexible circuit board.
